(19) United States
(12) Patent Application Publication
(10) Pub. No.: US 2025/0337405 A1
(43) Pub. Date: Oct. 30, 2025

(54) ELECTRONIC SWITCHING MODULE AND METHOD OF CONTROLLING SUCH A MODULE

(71) Applicant: STMicroelectronics International N.V., Geneva (CH)

(72) Inventor: Etienne FORAY, Grenoble (FR)

(73) Assignee: STMicroelectronics International N.V., Geneva (CH)

(21) Appl. No.: 19/170,451

(22) Filed: Apr. 4, 2025

(30) Foreign Application Priority Data
Apr. 26, 2024 (FR) FR2404366

(51) Int. Cl. H03K 17/16

(52) U.S. Cl. CPC H03K 17/161

(57) ABSTRACT

Provided is an electronic switching module including an input switching transistor connected to an input. The input switching transistor having a channel having a first type of conductivity. The electronic switching module includes a first switching transistor arranged between the input switching transistor and an output. The first switching transistor having a channel having said first type of conductivity. The electronic switching module includes an output compensation transistor disposed between the first switching transistor and said output. The output compensation transistor has a channel having a second type of conductivity, and the output compensation transistor is configured to reduce a leakage current to or from the output terminal.

### BACKGROUND

### Technical Field

Embodiments and implementations of the disclosure relate to an electronic switching module, in particular but not exclusively for analogue signal (sample-and-hold) applications.

### Description of the Related Art

In a sample-and-hold application, an electronic switching module receives a reference voltage at its input and, during a sample phase, delivers this voltage to a capacitor connected to its output terminal. During a “hold” phase, the electronic switching module is blocked and the output voltage is maintained by discharging the capacitor.

For example, such an electronic switching module can be used in a radio-frequency oscillator or in an analogue-to-digital converter, or even a digital-to-analogue converter.

More specifically, an electronic switching module generally comprises an input switching transistor and a main switching transistor between the input and output of this electronic switching module. The input switching transistor and the main switching transistor are configured to transfer the input reference voltage to the output of the electronic switching module.

In an electronic switching module, it is important to prevent the sampled voltage (i.e., the output voltage of the switching module) from being altered relative to the input reference voltage by charges that may be injected by the main switching transistor during its sample phase. These injected charges can cause errors, for example during digital-to-analogue conversion or analogue-to-digital conversion using said sampled voltage. Injected charges can also cause frequency variations and jitter.

Switching circuits using a compensation transistor with a channel of the same conductivity type as the channel of the main switching transistor are known. This compensation transistor is arranged between the main switching transistor and the output of the switching module. Such a compensation transistor can be used to compensate for charges injected by parasitic capacitance from the main switching transistor to the output of the switching module. However, such a compensation transistor may not sufficiently compensate for injected charges, or it may have junctions connected to the switching module output that can lead to current leakage. Such current leakage can cause the sampled voltage to drift over time. This drift leads to a loss of precision in the sampled voltage.

There is therefore a need to provide a solution for improving the accuracy of a reference voltage transfer via a switching module.

### BRIEF SUMMARY

According to one aspect, an electronic switching module is proposed comprising:
an input configured to receive a reference voltage and an output configured to deliver a sampled voltage,
a main switching transistor connected to the input and output, the main switching transistor having a channel having said first type of conductivity,
an output compensation transistor arranged between the main switching transistor and said output, the output compensation transistor having a channel having a second type of conductivity, the output compensation transistor being configured to reduce a leakage current to or from the output terminal,
control signals configured to control the main switching transistor and the output compensation transistor in order to transfer the input reference voltage to the output to obtain the sampled voltage.

The output compensation transistor compensates for charges injected into a triode region of the main switching transistor during transitions of the main switching transistor. This compensation is possible because the transistor has a channel having a different type of conductivity from that of the channel of the main switching transistor. Such an output compensation transistor avoids additional leakage to compensation. Such an output compensation transistor reduces any change in voltage at the output of the main switching transistor. In this way, the output compensation transistor provides a relatively constant sampled voltage. In particular, the output compensation transistor reduces an error on the sampled voltage independently of the production method, threshold voltage and temperature, and independently of the voltage of the control signals configured to control the main switching transistor and the output compensation transistor—the voltage of the control signals corresponding in particular to a supply voltage of the electronic switching module.

In an advantageous embodiment, the main switching transistor has a drain/source connected to the input, a source/drain connected to said output and a gate configured to receive a control signal C. The output compensation transistor has a drain and a source configured to receive a control signal C̅ inverted with respect to the control signal C, and a gate connected to said output.

Preferably, the main switching transistor is connected to the input via an input switching transistor, the input switching transistor having a channel having said first type of conductivity.

Advantageously, the input switching transistor has a drain/source connected to said input, a source/drain connected to the drain/source of the main switching transistor and a gate configured to receive a control signal A.

Preferably, the electronic switching module further comprises an auxiliary transistor having said second type of conductivity, the auxiliary transistor being configured to minimize a leakage current through the input switching transistor.

Advantageously, the auxiliary transistor has a drain configured to receive a supply voltage a source connected to the source of the input switching transistor, and a gate controlled by the control signal A.

In an advantageous embodiment, the electronic switching module further comprises an intermediate compensation transistor having a channel having the second type of conductivity between the input-in particular via the input switching transistor-and the main switching transistor, the intermediate compensation transistor being configured to compensate for leakage currents to or from the main switching transistor.

The intermediate compensation transistor compensates for charges injected by parasitic capacitance between the gate and the drain of the main switching transistor.

The intermediate compensation transistor thus makes it possible to reduce an error at the start of a sampling phase to keep the sampled voltage relatively stable.

Preferably, the intermediate compensation transistor comprises a drain and a source configured to receive a control signal C̅, and a gate connected to the drain of the main switching transistor.

Advantageously, the electronic switching module further comprises at least one pair of transistors between said input and a cold point, the transistors of this pair being connected by a node between these transistors to at least one sink in which the input switching transistor and the main switching transistor are arranged, said at least one pair of transistors being configured to reduce a leakage current between said input and said node.

Preferably, the transistor of said at least one pair of transistors which is connected to said input has a gate configured to receive a control signal B, and the transistor of said at least one pair of transistors which is connected to said cold point has a gate configured to receive a control signal B̅ inverted with respect to the control signal B.

In an advantageous embodiment, the electronic switching module further comprises an intermediate capacitive element having a first terminal connected to a node between the input switching transistor and the main switching transistor, and a second terminal connected to a cold point.

The intermediate capacitive element stabilizes the voltage and establishes a low impedance at the node between the input switching transistor and the main switching transistor. Thus, the intermediate capacitive element creates a low impedance path for parasitic charges injected by the input switching transistor and for the main switching transistor during their respective switching operations.

Preferably, the electronic switching module further comprises a capacitive output element having a first terminal connected to said output, and a second terminal connected to a cold point.

Advantageously, the input switching transistor, the main switching transistor, the output compensation transistor, the auxiliary transistor, the intermediate compensation transistor and the transistors of said at least one pair of transistors are metal-oxide gate field-effect transistors.

In an advantageous embodiment, the input switching transistor, the main switching transistor, and the transistors of said at least one pair of transistors are of the NMOS type, and the output compensation transistor, the auxiliary transistor and the intermediate compensation transistor are of the PMOS type.

In one variant, the input switching transistor, the main switching transistor, and the transistors of said at least one pair of transistors are of the PMOS type, and the output compensation transistor, the auxiliary transistor and the intermediate compensation transistor are of the NMOS type.

According to another aspect, an integrated circuit comprising an electronic switching module is proposed as described above.

According to another aspect, a method is proposed for controlling an intermediate electronic switching module as described above, the method comprising controlling the transistors of the electronic module via said control signals in order to transfer the input reference voltage to the output to obtain the sampled voltage.

Advantageously, the transistors of the electronic switching module are controlled simultaneously to transfer the input reference voltage to the output of the electronic switching module to obtain the sampled voltage.

Preferably, the transistors of the electronic module are controlled in a staggered manner,—in particular successively from the input to the output of the electronic switching module—to transfer the input reference voltage to the output of the electronic switching module to obtain the sampled voltage.

### BRIEF DESCRIPTION OF THE SEVERAL VIEWS OF THE DRAWINGS

Other advantages and features of the disclosure will become apparent upon examining the detailed description of non-limiting embodiments and implementations, and from the accompanying drawings, wherein:

FIG. 1 illustrates an embodiment of an integrated circuit IC.

FIG. 2 illustrates a first embodiment of a switching module SWC.

FIG. 3 illustrates a second embodiment of a switching module.

FIG. 4 illustrates a third embodiment of a switching module.

FIG. 5 illustrates a first implementation of a switching module control.

FIG. 6 illustrate a second implementation of a method for controlling a switching module.

### DETAILED DESCRIPTION

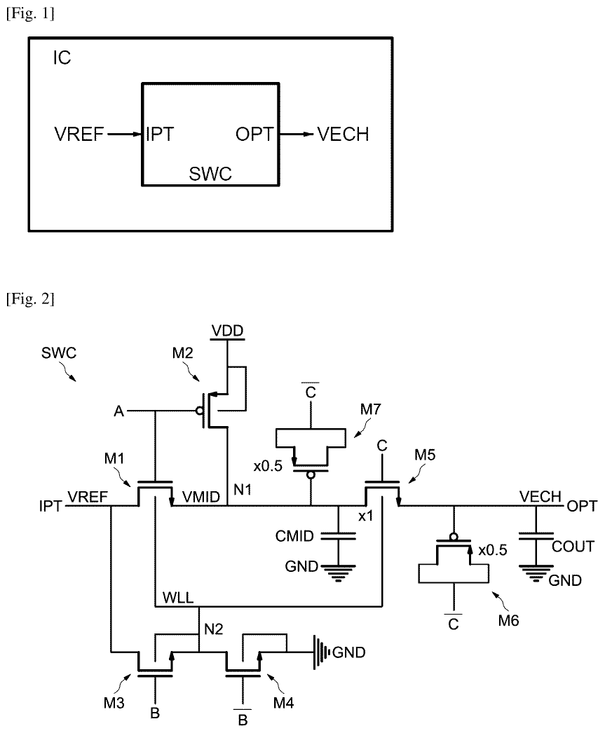

FIG. 1 illustrates an embodiment of an integrated circuit IC. The integrated circuit IC can be a microcontroller, for example.

The integrated circuit IC comprises an electronic switching module SWC. The switching module SWC can be a sample-and-hold module. The switching module SWC can also be used in an analogue-to-digital converter or a digital-to-analogue converter for example.

The switching module SWC is configured to sample the reference voltage VREF and to deliver a sampled voltage VECH corresponding to the sampled voltage.

For example, the reference voltage VREF is an analogue voltage which can be generated by a reference voltage generation circuit (not shown) of the integrated circuit IC.

The sampled voltage VECH can be used as a reference voltage for analogue circuits (such as regulators, oscillators, analogue-to-digital or digital-to-analogue converters).

The generation of the reference voltage VREF can be stopped when the sampled voltage VECH is used.

FIG. 2 illustrates a first embodiment of a switching module SWC.

The switching module SWC comprises an input switching transistor M1, an auxiliary transistor M2, a pair of transistors M3 and M4, a main switching transistor M5, an output compensation transistor M6 and an intermediate compensation transistor M7. These transistors M1, M2, M3, M4, M5, M6 and M7 are metal-oxide semiconductor field-effect transistors (MOSFET).

The switching module SWC also comprises a capacitive output element COUT and an intermediate capacitive element CMID.

The input switching transistor M1 is configured to receive the reference voltage VREF as input and to deliver a voltage VMID as output. The voltage VMID corresponds to the reference voltage VREF when the input switching transistor M1 is on.

The input switching transistor M1 has a channel having a first type of conductivity. For example, in the illustrated embodiment, the channel of the input switching transistor M1 is of the n type. The input switching transistor M1 is then an NMOS type transistor. In a not shown variant, the channel of the input switching transistor M1 is of the p type. The input switching transistor M1 is then a PMOS type transistor.

More particularly, in the illustrated embodiment, the input switching transistor M1 has a drain connected to the input of the switching module SWC so as to receive the reference voltage VREF.

The input switching transistor M1 also has a source connected to a first node N1 and configure to deliver the voltage VMID to this node N1.

The input switching transistor M1 also has a gate configured to receive a first control signal A. This first control signal A is used to control the input switching transistor M1 in such a way as to turn the input switching transistor M1 on or off.

The auxiliary transistor M2 is configured to minimize a leakage current between the input of the switching module SWC and the node N1.

In particular, the auxiliary transistor M2 has a channel with a second type of conductivity. For example, in the illustrated embodiment, the channel of the auxiliary transistor M2 is of the p type. The auxiliary transistor M2 is then a PMOS type transistor. In a not shown variant, the channel of the auxiliary transistor M2 is of the n type. The auxiliary transistor M2 is then an NMOS type transistor.

More particularly, the auxiliary transistor M2 has a drain configured to receive a supply voltage VDD.

The auxiliary transistor M2 also has a source configured to deliver a voltage VMID.

The auxiliary transistor M2 also has a gate configured to receive said first control signal A. This first control signal A is used to control the auxiliary transistor M2 to control the transistor M2 so as to turn it on or off.

The transistors M3 and M4 each have a channel having said first type of conductivity. For example, in the embodiment illustrate, the channels of transistors M3 and M4 are of the n type. The transistors M3 and M4 are then NMOS type transistors. In a variant that is not shown, the channels of transistors M3 and M4 are of the p type. The transistors M3 and M4 are then PMOS transistors.

In particular, the two transistors M3 and M4 are arranged between the input of the switching module and a cold point, in particular ground GND.

The two transistors M3 and M4 are connected via a second node N2 to a sink of the input switching transistor M1 and to a sink of the main switching transistor M5.

More particularly, a first transistor M3 comprises a drain connected to the input of the switching module so as to receive the voltage VREF. The first transistor M3 also comprises a source and a sink connected to the second node N2. The first transistor M3 also comprises a gate configured to receive a second control signal B.

The second transistor M4 comprises a drain connected to the second node N2. The second transistor M4 also comprises a source and a sink connected to a cold point, in particular ground GND. The first transistor M4 also comprises a gate configured to receive the second inverted control signal B.

The transistors M3 and M4 reduce, at equivalent resistance, the width of the input switching transistor M1 and main switching transistor M5 and to reduce leakage from these transistors M1 and M5. This improves the ratio of Iₒₙ to L_{off} of these transistors M1 and M5, where Iₒₙ is the drain current of the transistor M1 or M5 respectively, when the transistor M1 or M5 respectively is on and I_{off} is the leakage current of the transistor M1 or M5 respectively, when the transistor M1 or M5, is off.

The main switching transistor M5 is configured to receive as input the voltage VMID and to deliver as output a voltage VECH.

The main switching transistor M5 has a channel with said first type of conductivity. For example, in the embodiment shown, the channel of the main switching transistor M5 is of the n type. The main switching transistor M5 is then an NMOS type transistor. In a variant that is not shown, the channel of the main switching transistor M5 is of the p type. The main switching transistor M5 is then a PMOS type transistor.

More particularly, the main switching transistor M5 has a drain connected to the first node N1 to receive the voltage VMID. The main switching transistor M5 also has a source configured to deliver the sampling voltage. The main switching transistor M5 also has a gate configured to receive a third control signal C. This third control signal C is used to control the main switching transistor M5 so as to switch the main switching transistor M5 on or off.

The output compensation transistor M6 has a channel with said second type of conductivity. For example, in the illustrated embodiment, the channel of the transistor M6 is of the p type. The output compensation transistor M6 is then a PMOS type transistor. Alternatively, the channel of the output compensation transistor M6 is of the n type. The output compensation transistor M6 is then an NMOS type transistor.

The output compensation transistor M6 is smaller than the main switching transistor M5. For example, the transistor M6 is half the size of the main switching transistor M5.

More particularly, the output compensation transistor M6 has a drain and a source configured to receive the inverted third control signal. C̅. The output compensation transistor M6 also has a gate connected to the output of the sample and hold sampling/off circuit.

The output compensation transistor M6 is used to compensate for charges injected into the triode region of the main switching transistor M5 during transitions of the main switching transistor M5 (in particular when the gate-source voltage of the transistor M5 is higher than the threshold voltage of this transistor M5, when the transistor M5 is an NMOS transistor). This compensation is possible because the transistor M6 has a channel having a different type of conductivity than that of the transistor channel M5. This compensation is achieved without adding junctions connection to the VMID and VECH voltages.

Such an output compensation transistor M6 prevents additional leakage due to compensation.

Such an output compensation transistor M6 makes it possible reduce a change in the voltage at the output of the main switching transistor.

In this way, the output compensation transistor M6 makes it possible to obtain a relatively constant sampled voltage VECH, in particular over a wide range of control signal voltages C and C̅, for example between 1.6 volts and 3.6 volts.

In particular, the output compensation transistor M6 reduces an error in the sampled voltage VECH, independently of the production method, threshold voltage and temperature, and independently of the control signal voltages C and C̅. The voltage of the control signals C and C̅ correspond in particular to a supply voltage of the electronic switching module.

The intermediate compensation transistor M7 has a channel having said second type of conductivity. For example, in the embodiment illustrated, the channel of the intermediate compensation transistor M7 is of the p type. The intermediate compensation transistor M7 is then a PMOS type transistor. In a not shown variant, the channel of the intermediate compensation transistor M7 is of the n type. The intermediate compensation transistor M7 is then an NMOS type transistor.

The intermediate compensation transistor M7 is smaller in size than the main switching transistor M5. For example, the transistor M7 is half the size of the main switching transistor M5.

More particularly, the intermediate compensation transistor M7 has a drain and a source configured to receive the third inverted control signal C̅.

The intermediate compensation transistor M7 also has a gate connected to the first node N1.

The intermediate compensation transistor M7 compensates for charges injected by the parasitic capacitance between the gate and the drain of the main switching transistor M5.

The intermediate compensation transistor M7 thus reduces an error at the start of sampling phase to keep the sampled voltage VECH relatively stable.

The capacitive output element COUT has a first terminal connected to the output of the switching module and a second terminal connected to a cold point, in particular ground GND.

For example, the capacitive output element COUT has a capacitance greater than 1 pF, in particular between 5 pF and 10 pF.

The capacitive output element COUT is thus configured to maintain the sampled voltage VECH when the switching transistors M1 and M5 are off.

The intermediate capacitive element CMID has a first terminal connected to the first node N1 and a second terminal connected to a cold point, in particular ground GND.

The intermediate capacitive element CMID stabilizes the voltage VMID and establishes a low impedance on node N1, for example less than 1 kΩ for an alternating signal of a frequency of 10 GHz, this frequency corresponding to the frequency at which the main switching transistor M5 is turned on or off.

The intermediate capacitive element CMID has a capacitance greater than the parasitic capacitance of the main switching transistor M5. For example, the capacitance of the intermediate capacitive element CMID is five to ten times greater than that of said parasitic capacitances, in particular in the order of 100 fF.

More particularly, a capacitance in the order of 100 fF (femtofarads) is sufficient to enable the intermediate capacitive element CMID to ensure that the charges injected by the main switching transistor M5, in particular by its gate-drain parasitic capacitance (in the order of 1 fF) and by part of the channel, do not significantly impact the intermediate voltage VMID.

In a variant of the embodiment of FIG. 2, it is possible to provide a switching module that does not comprise an intermediate compensation transistor M7. In this case, only the output compensation transistor M6 and the intermediate capacitive element CMID can compensate for at least part of the charges injected by the main transistor M5.

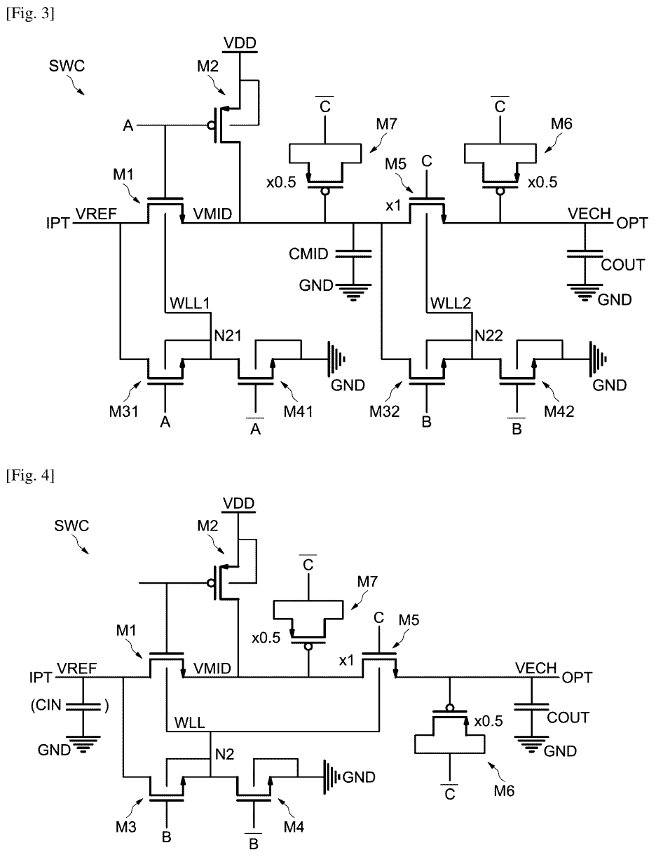

FIG. 3 illustrates a second embodiment of a switching module. In this embodiment, the switching module comprises the transistors M1, M2, M5, M6 and M7 described above, as well as the capacitive output element COUT and the intermediate capacitive element.

The switching module differs from the previously described sampling circuit in that it comprises two pairs of transistors M31, M41 and M32, M42.

The first pair of transistors comprises two transistors M31 and M41 arranged between the input of the switching module and a cold point, in particular ground GND.

The two transistors M31 and M41 are connected via a second node N21 to a sink of the input switching transistor M1.

The transistors M31 and M41 each have a channel having said first type of

conductivity. For example, in the embodiment shown, the channels of transistors M31 and M41 are of the n type. The transistors M31 and M41 are then NMOS type transistors. In a variant that is not shown, the channels of transistors M31 and M41 are of the p type. The transistors M31 and M41 are then PMOS type transistors.

More particularly, a first transistor M31 comprises a drain connected to the input of the switching module so as to receive the voltage VREF.

The first transistor M31 also comprises a source and a sink connected to the second node N21.

The first transistor M31 also comprises a gate configured to receive a second control signal B.

A second transistor M41 comprises a drain connected to the second node N21.

The second transistor M41 also comprises a source and a sink connected to a cold point, in particular ground GND.

The first transistor M41 also comprises a gate configured to receive the second inverted control signal B̅.

The transistors M31 and M41 make it possible, at equivalent resistance, to reduce the width of the input switching transistor M1 and reduce leakages from this transistor M1. This improves the Iₒₙ to l_{off} ratio of the input switching transistor M1, where Iₒₙ is the drain current of this transistor M1 when this transistor M1 is on and L_{off} is the leakage current of the transistor M1 when this transistor M1 is off.

In particular, the second pair of transistors comprises two transistors M32 and M42 arranged between the input of the switching module and a cold point, in particular ground GND.

The two transistors M32 and M42 are connected via a second node N22 to a sink of the main switching transistor M5.

The transistors M32 and M42 each have a channel having said first type of conductivity. For example, in the embodiment shown, the channels of the transistors M32 and M42 are of the n type. The transistors M32 and M42 are then NMOS type transistors. In a not shown variant, the channels of transistors M32 and M42 are of the p type. The transistors M32 and M42 are then PMOS transistors.

More particularly, a first transistor M32 comprises a drain connected to the input of the switching module so as to receive the voltage VREF.

The first transistor M32 also comprises a source and a sink connected to the second node N22.

The first transistor M32 also comprises a gate configured to receive a second control signal B.

A second transistor M42 comprises a drain connected to the second node N22.

The second transistor M42 also comprises a source and a sink connected to a cold point, in particular ground GND.

The first transistor M42 also comprises a gate configured to receive the second inverted control signal B̅.

The transistors M32 and M42 make it possible to reduce the on-state of the main switching transistor M5. The transistors M32 and M42 make it possible, at equivalent resistance, to reduce the width of the main switching transistor M5 and reduce leakage from this transistor M5. This improves the ratio of Iₒₙ to I_{off} of the main switching transistor M5, where Iₒₙ is the drain current of the transistor M5 when this transistor M5 is on and I_{off} is the leakage current of the transistor M5 when this transistor M5 is off.

In such an electronic switching module SWC, the switching transistors M1 and M5 can be arranged in separate sinks. This makes it possible to use a sink of smaller size for the main switching transistor M5, so that this main switching transistor injects less charge.

FIG. 4 illustrates a third embodiment of a switching module. In this embodiment, the switching module comprises the transistors M1, M2, M3, M4, M5, M6 and M7 described above, as well as the capacitive output element COUT.

The switching module differs from those described above in that it does not include an intermediate capacitive element CMID.

Furthermore, the input switching transistor M1 has a higher W/L ratio between its channel width and its channel length than the main switching transistor M5. In particular, the W/L ratio of the input switching transistor M1 can be more than twice the W/L ratio of the main switching transistor M5, for example between two times and a hundred times the W/L ratio of the transistor M5, in particular in the order of ten times that of the transistor M5. For example, the W/L ratio of the input switching transistor M1 is greater than 5, for example between 5 and 100, in particular in the order of 20.

The switching module may optionally have a capacitive input element CIN. The capacitive input element CIN has a capacitance greater than 1 fF, in particular less than 100 pF, for example in the order of 200 fF.

The capacitive input element CIN makes it possible to create a low impedance path, for example less than 1 kΩ, for the charges injected by the switching transistor M5 to node N1 and by input switching transistor M1 during their switching. This makes is possible to reduce or even avoid disturbances to the input reference voltage VREF.

In this embodiment, the switching module comprises a single pair of transistors M3, M4. Nevertheless, it is possible to provide two pairs of transistors M31 and MM41, M32 and M42 as previously described in relation to FIG. 3.

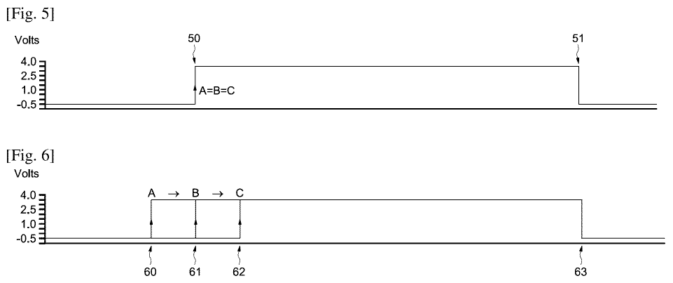

FIG. 5 illustrates a first implementation of a switching module control such as those described in connection with FIGS. 1 to 4.

In this implementation, the first control signal A, the second control signal B and the third control signal C operate simultaneously. In particular, these control signals A, B, C are configured to turn on the transistors M1, M3 and M5 simultaneously, in step 50, and to turn them off simultaneously as well, in step 51.

FIG. 6 illustrate a second implementation of a method for controlling a switching module such as those described in relation to FIGS. 1 to 4.

In this implementation, the first control signal A, the second control signal B and the third control signal C are configured to turn on transistors M1, M3, M4 and M5 in a staggered manner and to also turn them off simultaneously.

In particular, the first control signal is adapted to turn on the input switching transistor initially, in step 60.

The second control signal B is adapted to turn on the transistor M3 after input switching transistor M1, in step 61, in particular after a time of between 1 nanosecond and 100 microseconds, and before the main switching transistor M5.

The third control signal C is adapted to turn on the main switching transistor M5 after the transistor M3, in step 62, in particular after a time of between 1 nanosecond and 100 microseconds.

The transistors M1, M3, M4 and M5 then are kept on until the COUT capacitive element is charged.

Then, the control signals A, B, C are configured to turn off the transistors M1, M3 and M5 also simultaneously, in step 63.

Such a control method makes it possible to prevent the voltage VREF be altered when it is transferred to the output of the switching module to obtain the voltage VECH.

Electronic switching module may be summarized as including: an input (IPT) configure to receive a reference voltage and an output (OPT) configured to deliver a sampled voltage, a main switching transistor (M5) connected to the input (IPT) and to the output (OPT), the main switching transistor (M5) having a channel having said first type of conductivity, an output compensation transistor (M6) arranged between the main switching transistor (M5) and said output (OPT), the output compensation transistor (M6) having a channel having a second type of conductivity, the output compensation transistor (M6) being configured to reduce a leakage current to or from the output terminal, control signals (C,C̅) configured to control the main switching transistor (M5) and the output compensation transistor (M6) in order to transfer the input reference voltage (IPT) to the output (OPT) to obtain the sampled voltage (VECH).

The main switching transistor (M5) may have a drain/source connected to the input, a source/drain connected to said output and a gate configured to receive a control signal C, and the output compensation transistor (M6) may have a drain and a source configured to receive a control signal C̅inverted with respect to the control signal C, and a gate connected to said output.

The main switching transistor may be connected to the input (IPT) via an input switching transistor (M1), the input switching transistor (M1) having a channel having said first type of conductivity.

The input switching transistor (M1) may have a drain/source connected to said input, a source/drain connected to the drain/source of the main switching transistor and a gate configure to receive a control signal A.

Module may further include an auxiliary transistor (M2) having said second type of conductivity, the auxiliary transistor being configured to minimize a leakage current through the input switching transistor.

The auxiliary transistor (M2) may have a drain configured to receive a supply voltage from a source connected to the source of the input switching transistor (M1), and a gate controlled by the control signal A.

Module may further include an intermediate compensation transistor (M7) having a channel having the second type of conductivity between the input (IPT) and the main switching transistor (M5), the intermediate compensation transistor (M7) being configured to compensate for leakage currents to or from the main switching transistor (M5).

The intermediate compensation transistor (M7) may include a drain and a source configured to receive the control signal C, and a gate connected to the drain/source of the main switching transistor (M7).

Module may further include at least one pair of transistors (M3, M4) between said input (IPT) and a cold point (GND), the transistors of this pair being connected via a node (N2) between these transistors to at least one sink wherein the input switching transistor (M1) and the main switching transistor (M5) may be arranged, said at least one pair of transistors being configured to reduce a leakage current between said input (IPT) and said node (N2).

The transistor of said at least one pair of transistors which may be connected to said input (IPT) may have a gate configured to receive a control signal B, and the transistor of said at least one pair of transistors which may be connected to said cold point may have a gate configured to receive a control signal B̅ inverted with respect to the control signal B.

Module may further include an intermediate capacitive element (CMID) having a first terminal connected to a node (N1) between the input switching transistor (M1) and the main switching transistor (M5), and a second terminal connected to a cold point (GND).

Module may further include a capacitive output element (COUT) having a first terminal connected to said output, and a second terminal connected to a cold point (GND).

The input switching transistor (M1), the main switching transistor (M5), the output compensation transistor (M6), the auxiliary transistor (M2), the intermediate compensation transistor (M7) and the transistors (M3, M4) of said at least one pair of transistors may be metal-oxide gate field-effect transistors.

The input switching transistor (M1), the main switching transistor (M5), and the transistors (M3, M4) of said at least one pair of transistors (M3, M4) may be of the NMOS type, and the output compensation transistor (M6), the auxiliary transistor (M2) and intermediate compensation transistor (M7) may be of the PMOS type.

The input switching transistor (M1), the main switching transistor (M5), and the transistors (M3, M4) of said at least one pair of transistors (M3, M4) may be of the PMOS type, and the output compensation transistor (M6), the auxiliary transistor (M2) and the intermediate compensation transistor (M7) may be of the NMOS type.

Integrated circuit may include an electronic switching module (SWC).

Method for controlling an intermediate electronic switching module may be summarized as including driving the transistors of the electronic module via said control signals (C, C̅) in order to transfer the input reference voltage (IPT) to the output (OPT) to obtain the sampled voltage (VECH).

The transistors of the electronic switching module may be simultaneously controlled to transfer the input reference voltage (IPT) to the output (OPT) of the electronic switching module to obtain the sampled voltage (VECH).

The transistors of the electronic switching module may be controlled in a staggered manner to transfer the input reference voltage (IPT) to the output (OPT) of the electronic switching module to obtain the sampled voltage (VECH).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic switching module, comprising:
an input configured to receive a reference voltage,
an output configured to output a sampled voltage,
a first switching transistor connected to the input and to the output, the first switching transistor having a channel having a first type of conductivity, and
an output compensation transistor arranged between the first switching transistor and the output, the output compensation transistor having a channel having a second type of conductivity, the output compensation transistor being configured to reduce a leakage current to or from the output,
wherein the first switching transistor and the output compensation transistor are controlled by control signals to transfer the reference voltage to the output to obtain the sampled voltage.

2. The module according to claim 1, wherein:
the first switching transistor has a drain or a source connected to the input, another of the source or the drain connected to the output and a gate configured to receive a first control signal of the control signals, and
the output compensation transistor has a drain and a source configured to receive a second control signal of the control signals, wherein the second control signal is inverted with respect to the first control signal, and wherein the gate of the output compensation transistor is connected to said output.

3. The module according to claim 1, wherein the first switching transistor is connected to the input via an input switching transistor, the input switching transistor having a channel having said first type of conductivity.

4. The module according to claim 2, wherein the input switching transistor has a drain or source connected to said input, another of the source or the drain connected to the drain or the source of the first switching transistor and a gate configured to receive an input switching transistor control signal.

5. The module according to claim 4, further comprising:
an auxiliary transistor having said second type of conductivity, the auxiliary transistor being configured to minimize a leakage current through the input switching transistor.

6. The module according to claim 5, wherein the auxiliary transistor has a drain configured to receive a supply voltage from a source connected to the source of the input switching transistor, and a gate controlled by the input switching transistor control signal.

7. The module according to claim 1, further comprising:
an intermediate compensation transistor having a channel having the second type of conductivity between the input and the first switching transistor, the intermediate compensation transistor being configured to compensate for leakage currents to or from the first switching transistor.

8. The module according to claim 7, wherein the intermediate compensation transistor includes a drain and a source configured to receive a second control signal of the control signals, and a gate connected to the drain or the source of the first switching transistor.

9. The module according to claim 1, further comprising:
at least one pair of transistors between said input and ground, the at least one pair of transistors having a node therebetween coupled to at least one sink, said at least one pair of transistors being configured to reduce a leakage current between said input and said node.

10. The module according to claim 9, wherein a first transistor of said at least one pair of transistors is connected to said input and has a gate configured to receive a third control signal, and a second transistor of said at least one pair of transistors is connected to said ground and has a gate configured to receive a fourth control signal that is inverted with respect to the third control signal.

11. The module according to claim 3, further comprising:
an intermediate capacitive element having a first terminal connected to a node between the input switching transistor and the first switching transistor and a second terminal connected to ground.

12. The module according to claim 1, further comprising:
a capacitive output element having a first terminal connected to said output and a second terminal connected to ground.

13. An integrated circuit comprising:
an electronic switching module including:
an input configured to receive a reference voltage,
an output configured to output a sampled voltage,
a first switching transistor connected to the input and to the output, the first switching transistor having a channel having a first type of conductivity, and
an output compensation transistor arranged between the first switching transistor and the output, the output compensation transistor having a channel having a second type of conductivity, the output compensation transistor being configured to reduce a leakage current to or from the output,
wherein the first switching transistor and the output compensation transistor are controlled by control signals to transfer the reference voltage to the output to obtain the sampled voltage.

14. The integrated circuit to claim 13, wherein:
the first switching transistor has a drain or a source connected to the input, another of the source or the drain connected to the output and a gate configured to receive a first control signal of the control signals, and
the output compensation transistor has a drain and a source configured to receive a second control signal of the control signals, wherein the second control signal is inverted with respect to the first control signal, and wherein the gate of the output compensation transistor is connected to said output.

15. The integrated circuit according to claim 13, wherein the first switching transistor is connected to the input via an input switching transistor, the input switching transistor having a channel having said first type of conductivity.

16. The integrated circuit according to claim 14, wherein the input switching transistor has a drain or source connected to said input, another of the source or the drain connected to the drain or the source of the first switching transistor and a gate configured to receive an input switching transistor control signal.

17. The integrated circuit according to claim 16, wherein the electronic switching module includes:
an auxiliary transistor having said second type of conductivity, the auxiliary transistor being configured to minimize a leakage current through the input switching transistor.

18. A method for controlling an intermediate electronic switching module, comprising:
driving transistors of the electronic module using control signals to transfer a reference voltage received at an input to a sampled voltage provided at an output,
wherein a first switching transistor of the transistors is connected to the input and to the output, the first switching transistor having a channel having a first type of conductivity, and an output compensation transistor of the transistors is arranged between the first switching transistor and the output, the output compensation transistor having a channel having a second type of conductivity, the output compensation transistor being configured to reduce a leakage current to or from the output.

19. The method according to claim 18, wherein the first switching transistor and the output compensation transistor of the electronic switching module are simultaneously controlled to transfer the reference voltage to the output of the electronic switching module to obtain the sampled voltage.

20. The method according to claim 18, wherein the first switching transistor and the output compensation transistor of the electronic switching module are controlled in a staggered manner to transfer the reference voltage to the output to obtain the sampled voltage.
